(19) United States
(12) Patent Application Publication
(10) Pub. No.: US 2006/0000796 A1
(43) Pub. Date: Jan. 5, 2006

(54) Method for controlling critical dimensions and etch bias

(76) Inventors: Elliot Tan, Portland, OR (US); James Jeong, Beaverton, OR (US); Qiang Fu, Portland, OR (US)

Correspondence Address: INTEL/BLAKELY, 12400 WILSHIRE BOULEVARD, SEVENTH FLOOR, LOS ANGELES, CA, 90025-1030, US

(21) Appl. No.: 10/882,982

(22) Filed: Jun. 30, 2004

(51) Int. Cl. B44C 1/22; H01L 21/302

(52) U.S. Cl. 216/37; 216/67; 438/706; 438/710

(57) ABSTRACT

In one embodiment a method is provided. The method, comprises performing at least one deposition operation to laminate portions of a patterned photoresist that experiences degradation when bombarded with an etchant plasma during a subsequent plasma etching operation and performing the plasma etching operation.

### FIELD OF THE INVENTION

Embodiments of the invention relate to etching, and in particular to controlling critical particular dimensions in the 150 nm range.

### BACKGROUND

The dimensions of the transistors and wiring interconnects that make up integrated circuits are becoming smaller and smaller. As a result, the resolution of optical lithography tools used to print these smaller features have increased, for example by reducing the imaging wavelengths of lasers used to expose photoresists. Because the imaging wavelengths of the lasers have shrunk, the thicknesses of photoresists have also been reduced to compensate for the reduced depth or focus of the lasers. However, photoresists of thickness 200 nm and below do not resist etchants very well, and have an etch bias that increases a critical dimension of a feature being etched. For example, with a 200 nm thick photoresist, the etch bias may be between 50 nm and 60 nm which increases the size of a feature with a critical dimension (CD) of 100 nm, significantly.

The above-mentioned problem of an increase in critical dimension due to an increase in etch bias is illustrated in FIGS. 1A, and 1B of the drawings. Referring to FIG. 1A a substrate 100, for example an interlayer dielectric (ILD), underlies a photoresist layer 102 which has been patterned and developed to form a gap 104 therein, defined by two residual bits of photoresist designated by reference numerals 106, and 108, respectively. The residual bit of photoresist 106 includes a generally flat upper surface 106.1 and an inclined surface 106.2 which slopes downwardly towards the substrate 100. Likewise, the bit of photoresist 108 includes a generally flat upper surface 108.1, and an inclined surface 108.2 which slopes downwardly towards the substrate 100. The gap 104 is defined between the two inclined surfaces 106.2, and 108.2. As will be seen, the gap has a fixed gap width, indicated by reference numeral 110. The photoresist 102 with the gap 104 from therein, selectively allows high energy etchant plasma 111 to pass through the gap 104 in the photoresist 102 thereby to etch a via 112 in the substrate 110. As will be seen, the via has sidewalls 114 and 116 which are spaced apart by a critical dimension (CD) which has to be tightly controlled. Further, the via 112 includes a blind end 117 which continues to grow under exposure of the high energy etchant plasma 111 until it reaches an upper surface 118.1 of an etch stop layer 118. FIG. 1B illustrates what happens to the critical dimension (CD) as the via 112 continues to grow towards the etch stop layer 118. Referring to FIG. 1B it will be seen that parts of the photoresist 106, and 108 degrades or is removed by the high energy plasma etchant 111 causing the inclined walls 106.2 and 108.2 to move apart, thereby to increase the width of the gap 110. As a result of the widening of the gap 110, the high energy etchant plasma 111 is able to make contact with a wider section of the substrate 100, resulting in the critical dimension (CD) increasing. In FIG. 1B the (CD) is the distance between the sidewalls 114 and 116 shown in solid lines and is greater than the (CD) of FIG. 1A which is illustrated by the distance between the sidewalls 114 and 116 shown in dotted lines in FIG. 1B.

Instead of using photoresist, a hard mask such as silicon carbide may be used to resist the plasma etchants and minimize etch bias. However, it is difficult to remove the hard mask after it has served its role in the etch process; the hard mask is usually left behind in the device. The dielectric properties of the hard mask will contribute to the capacitance of the device and degrades its speed performance. Further, the use of hard mask adds a substantial number of operations to the device manufacturing process and has to be patterned by lithography and etch processes.

### BRIEF DESCRIPTION OF THE DRAWINGS

FIG. 1A, and 1B illustrate how a critical dimension (CD) of a feature being etched in a substrate increases due to an etch bias; and

FIGS. 2A to 2D illustrate an etching technique in accordance with one embodiment of the invention.

### DETAILED DESCRIPTION

In the following description, for purposes of explanation, numerous specific details are set forth in order to provide a thorough understanding of the invention. It will be apparent, however, to one skilled in the art that the invention can be practiced without these specific details. In other instances, structures and devices are shown in block diagram form in order to avoid obscuring the invention.

Reference in this specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not other embodiments.

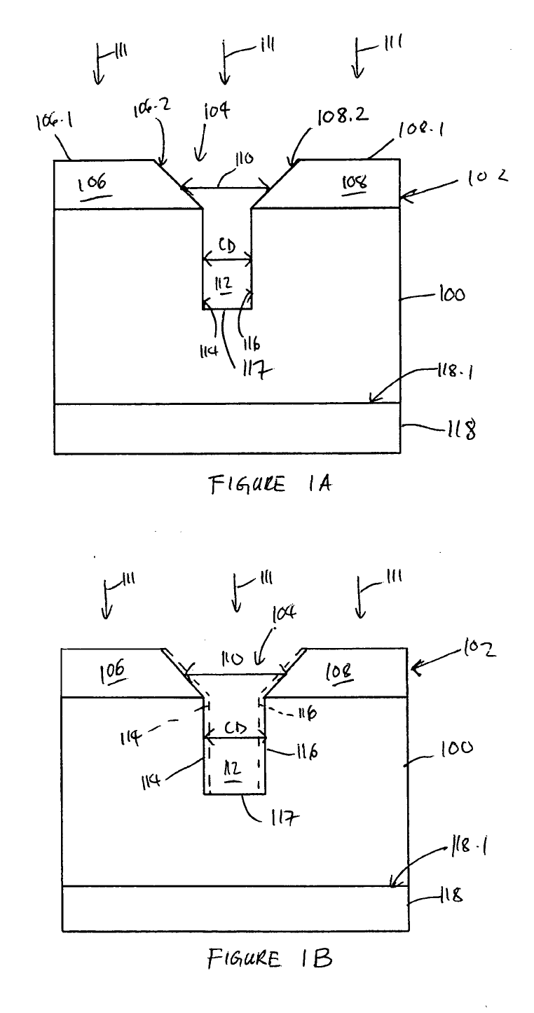

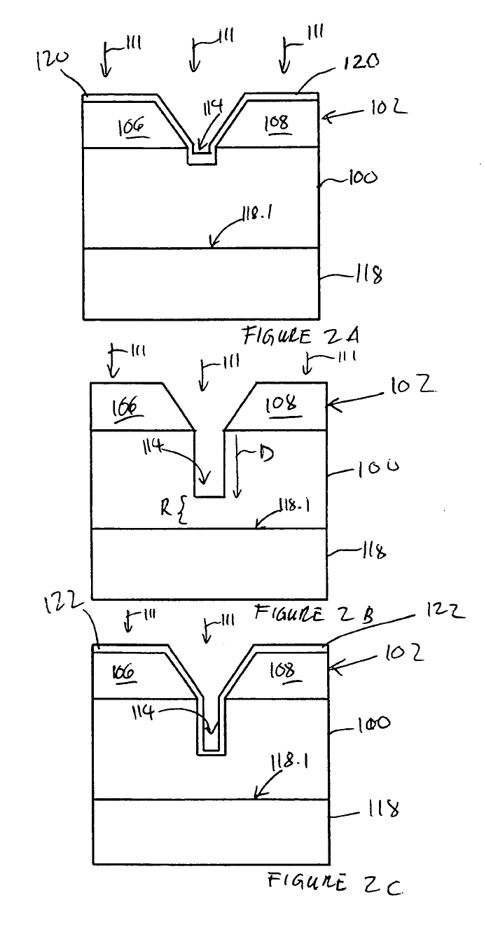

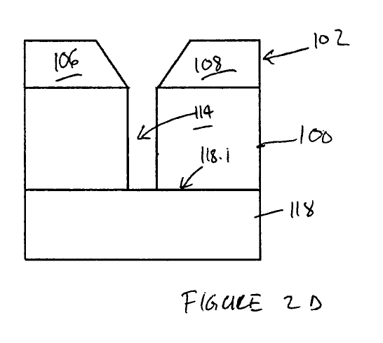

FIGS. 2A to 2D of the drawings illustrate one technique for etching a feature in a substrate while controlling a critical dimension (CD), in accordance with one embodiment of the invention. In FIGS. 2A to 2D, the features/components already described with reference to FIGS. 1A, and 1B of the drawings have been assigned the same reference numerals as in FIGS. 1A, and 1B. Thus for example, the substrate that is being etched is indicated by reference numeral 100. In this regard, it should be borne in mind that the substrate 100 may represent any substrate in which a feature such as a transistor, or an interconnect, requiring tight control of a critical dimension (CD), is being etched. Referring to FIG. 2A of the drawings, in accordance with one embodiment, a first polymerization step is performed in which a polymer layer 120 is deposited on the exposed surfaces of the photoresist 102. As can be seen from FIG. 2B of the drawings, a main etching step is performed in which a main or substantial portion D of the substrate 100 is etched, leaving an unetched remainder R. During the main etching step, the polymer layer 120 is at least partly degraded or removed through bombardment by the high energy plasma etchant 111. As a result, the main etching step is interrupted in order to perform a second polymerization step, illustrated in FIG. 2C of the drawings, in which a polymerization layer 122 is deposited on the exposed surfaces of the photoresist 102. As will be seen, the polymer layer 122 also extends into the via 114. Thereafter, the etching of the substrate 100 continues so that the remainder R is etched until the via 114 extends to the etch stop layer 118.

Although, in the above embodiment of the invention, two polymerization steps have been described. It is important to appreciate that in other embodiments of the invention there may be more than two polymerization steps. Further, the order in which the etching steps described with reference to FIGS. 2A to 2D may be different in accordance with other embodiments of the invention. For example, instead of starting with a polymerization step, the main etching step may be performed first. However, in this case the extent to which the substrate 100 is etched during the first main etching step will have to be reduced so that the first polymerization step can be performed before the photoresist 102 degrades to such an extent that there is an increase in the critical dimension (CD). Based on the foregoing, it will be seen that, in accordance with one embodiment of the invention, an etching technique is disclosed for etching a substrate 100, wherein at least one polymerization step is performed, in addition to a main etching step, in order to deposit a polymer layer to protect the photoresist used in the etching of the substrate.

In a first example, using a 250 nm photoresist, an etch bias of less than 20 nm was achieved by including a polymerization step with a main etching step. The parameters used for this first example, are illustrated in the following Table 1:

TABLE 1

| | Pressure | Power | Gas1: C4F8 | Gas2: N2 | Gas3: CO |
|---|---|---|---|---|---|
| Step 1 | 100 to | 1000 to | 15 to 20 | 100 to 200 sccm | 50 to 100 |
| | 200 mT | 1500 W | sccm | | sccm |
| Step 2 | 200 to | 2000 to | 5 to 10 | 500 to 700 sccm | 50 to 100 |
| | 400 mT | 3000 W | sccm | | sccm |

| | |
|---|---|
| Step 3 | Repeat Step 1 for Polymer Deposition |
| Step 4 | Repeat Step 2 for ILD removal |
| . | |
| . | |
| . | |
| Final | Use process parameters suitable for etch stop layer removal |
| Step | |

Referring to Table 1, the first step removes a small amount of the substrate 100 but is designed primarily to reduce the dimensions of the via entrance (gap 104) by polymer deposition. This mitigates an increase in the critical dimension (CD) during the main etch (second step) where the substrate 100 is aggressively removed. The process is then repeated until etching is complete.

In a second example, a four step etching procedure was performed. The parameters for the various steps in the etching procedure are shown in Table 2 below.

TABLE 2

| | | | Gas1: | Gas2: | Gas3: | Gas3: |
|---|---|---|---|---|---|---|
| | Pressure | Power | C4F8 | N2 | CO | AR |
| Step 1 | 30 to 60 mT | 1000 W | 15 sccm | 100 sccm | 30 sccm | — |
| Step 2 | 80 to | 2000 W | 5 sccm | 500 sccm | 30 sccm | — |
| | 150 mT | | | | | |
| Step 3 | 30 to 60 mT | 1000 W | 15 sccm | 100 sccm | 30 sccm | — |
| Step 4 | 10 to 30 mT | 3000 W | 10 sccm | 200 sccm | — | 2000 |
| | | | | | | sccm |

Referring to Table 2, steps 1 and 3 are polymerization steps, whereas steps 2 and 4 are steps for etching the substrate 100.

Although the present invention has been described with reference to specific exemplary embodiments, it will be evident that the various modification and changes can be made to these embodiments without departing from the broader spirit of the invention as set forth in the claims. Accordingly, the specification and drawings are to be regarded in an illustrative sense rather than in a restrictive sense.

What is claimed is:

1. A method, comprising:
performing at least one deposition operation to laminate portions of a photoresist that experiences degradation when bombarded with an etchant plasma during a subsequent plasma etching operation; and
performing the plasma etching operation.

2. The method of claim 1, wherein the deposition operation and the plasma etching operation are performed using the same equipment.

3. The method of claim 1, comprising performing two deposition operations and performing two plasma etching operations.

4. The method of claim 3, wherein the first deposition operation laminates an entrance of a via in the substrate.

5. The method of claim 4, wherein the first plasma etching operation etches a major portion of an interlayer dielectric of a substrate underlying the photoresist.

6. The method of claim 5, wherein the second deposition operation laminates sidewalls of the via.

7. The method of claim 6, wherein the second plasma etching operation etches a remaining portion of the interlayer dielectric, and is selective to an etch stop layer underlying the interlayer dielectric.

8. The method of claim 7, wherein performing each deposition operation comprises selecting a plasma chemistry and operational parameters of the equipment so that a polymerization point is reached and deposition occurs.

9. The method of claim 8, wherein performing each etching operation comprises selecting a plasma chemistry and operational parameters of the equipment so that etching occurs and the polymerization point is not reached.

10. The method of claim 8, wherein for the first and second deposition operations, the plasma chemistry comprises C4F8/C0/N2 with a concentration of 15 cm³, 30 cm³ and 100 cm³, respectively and with operational parameters of the equipment being set at a pressure of 30-60 mT and a power of 1000 W.

11. The method of claim 8, wherein for the first etching operation, the plasma chemistry comprises C4F8/CO/N2 with concentrations of 5 cm³, 30 cm³, and 500 cm³, respectively, and with the operational parameters of the equipment being set to a pressure of 80-150 mT and a pressure of 2000 W.

12. The method of claim 9, wherein for the second etching operation, the plasma chemistry comprises C4F8/AR/N2 with concentrations of 10 cm³, 2000 cm³, and 200 cm³, respectively, with the operational parameters of the equipment being set to a pressure of 10-50 mT and a power of 3000 W.

13. The method of claim 9, wherein the plasma chemistry for the first and second deposition operations comprise C4F8/CO/N2 with concentrations of 15-20 cm³, 50-100 cm³, and 100-200 cm³, with the operational parameters of the equipment being set to a pressure of 100-200 mT, and to a power of 1000-1500 W.

14. The method of claim 9, wherein for the first and second etching operations, the plasma chemistry comprises C4F8/CO/N2 with concentrations of 5-10 cm³, 50-100 cm³, and 500-700 cm³, respectively, and with the operational parameters of the equipment being set to a pressure of 200-400 mT and to a pressure of 2000-3000 W.

15. A method, comprising:
reducing an increase in a critical dimension (CD) due to an etch bias of a main etching operation by coating portions of a photoresist overlying a substrate with a material; and
performing the main etching operation to etch the substrate through the photoresist.

16. The method of claim 15, wherein the material comprises a polymer.

17. The method of claim 16, wherein the polymer is deposited at an entrance of a via in the photoresist during a first polymerization step performed before the main etching operation

18. The method of claim 17, wherein the main etching operation is performed in two stages, a first of which etches a substantial portion of the substrate and the second of which etches a remainder of the substrate up to an underlying etch stop layer and is selective to the underlying etch stop layer.

19. The method of claim 18, wherein a second polymerization step is performed before the second stage of the main etching operation to line sidewalls of the via.

20. The method of claim 19, wherein the same equipment is used to perform the polymerization and main etching operations.

21. A method, comprising:
performing a plasma etching operation to etch a feature in a substrate through a photoresist overlying the substrate; and
interrupting the plasma etching process at least once to perform a rebuilding operation to rebuild portions of the photoresist damaged by the plasma etching operation.

22. The method of claim 21, wherein the rebuilding operation comprises the process parameters for the plasma etching operation modified so that a polymerization point is reached at which polymer deposition on the photoresist occurs.
